(19) United States
(12) Patent Application Publication
(10) Pub. No.: US 2006/0220712 A1
(43) Pub. Date: Oct. 5, 2006

(54) Frequency double circuit

(75) Inventors: Xu-Shan Lin, Shenzhen (CN); Yong-Xing You, Shenzhen (CN)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: HON HAI Precision Industry CO., LTD., Tu-Cheng City (TW)

(21) Appl. No.: 11/360,843

(22) Filed: Feb. 23, 2006

(30) Foreign Application Priority Data
Apr. 3, 2005 (CN) 200510033996.7

(51) Int. Cl. H03L 7/06

(52) U.S. Cl. 327/159

(57) ABSTRACT

A frequency double circuit includes an input terminal, a first voltage source, a multiplier, a second voltage source, and an output terminal. The input terminal receives an input signal and outputs to the first voltage source. The first voltage source filters out a direct current signal of the input signal. The multiplier includes two input ends receiving the input signal from the first voltage source for linear multiplication and gets a double frequency signal. The double frequency signal is output to the second voltage source for filtering out a direct current signal of the double frequency signal. The output terminal outputs the double frequency signal from the second voltage source.

### BACKGROUND

1. Field of the Invention

The present invention relates to a frequency double circuit, and more particularly to a frequency double circuit which has a multiplier.

2. General Background

In general, in a design and experiment of electronic products, variety of signals with different frequency is produced by a frequency double circuit.

Referring to FIG. 2, a conventional frequency double circuit that uses the Phase-Locked Loop (PLL) technique is show. A basic framework of the frequency double circuit includes a phase-frequency detector (PFD) 1, a charge pump loop filter (CPF) 12, a voltage control oscillator (VCO) 13, and a divider 14. The PFD 11 receives a signal Sin and a feedback signal from the divider 14. The PFD 11 detects a difference in frequency between the signal Sin and the feedback signal, then generates an up or down control signal. The PFD 11 outputs the up or down control signal to the CPF 12. The CPF 12 converts the control signal to a control voltage and outputs the control voltage to the VCO 13. If the PFD 11 produces an up signal, frequency of the VCO 13 increases. If the PFD 11 produces a down signal, frequency of the VCO 13 decreases. Frequency of the VCO 13 stabilizes once the signal Sin and the feedback signal have a same frequency. The VCO 13 outputs a signal Sout that is input to the divider 14. The divider 14 decreases frequency of the VCO 13. Therefore, frequency of the Sout is equal to several times of frequency of the Sin.

Although the conventional frequency double circuit can produce a double frequency signal, the signal always has a delay because of a feeding back and a comparison. Furthermore, electronic structure of the conventional frequency double circuit is complex due to many electronic components.

What is needed is a frequency double circuit that has a simple structure and low cost.

### SUMMARY

An exemplary frequency double circuit includes an input terminal, a first voltage source, a multiplier, a second voltage source, and an output terminal. The input terminal receives an input signal and outputs to the first voltage source. The first voltage source filters out a direct current signal of the input signal. The multiplier includes two input ends receiving the input signal from the first voltage source for linear multiplication and gets a double frequency signal. The double frequency signal is output to the second voltage source for filtering out a direct current signal of the double frequency signal. The output terminal outputs the double frequency signal from the second voltage source.

Other advantages and novel features will become more apparent from the following detailed description when taken in conjunction with the accompanying drawings, in which:

### BRIEF DESCRIPTION OF THE DRAWINGS

FIG. 1 is a circuit diagram of a frequency double circuit in accordance with a preferred embodiment of the present invention; and

FIG. 2 is a framework of a conventional frequency double circuit based on the PLL technique.

### DETAILED DESCRIPTION OF THE EMBODIMENTS

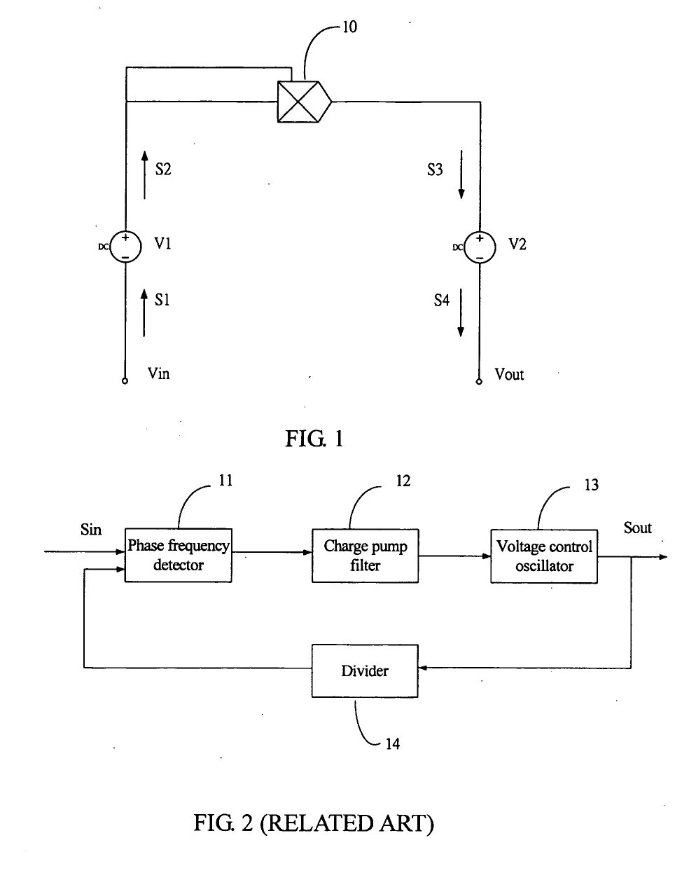

Referring to FIG. 1, a frequency double circuit in accordance with a preferred embodiment of the present invention is shown. The frequency double circuit includes a multiplier 10, a signal input terminal Vin, a first voltage source V1, a second voltage source V2, and a signal output terminal Vout. The first voltage source Vi and the second voltage source V2 are direct current voltage sources. An input signal S1 is input to the first voltage source V1 via the signal input terminal Vin. Then the first voltage source V1 outputs a signal S2 to two input ends of the multiplier 10 for linear multiplication and gets a double frequency signal S3. The multiplier 10 outputs the double frequency signal S3 to the second voltage source V2, and the second voltage source V2 outputs a signal S4 to the signal output terminal Vout.

Supposing that the input signal S1 is a sine wave, the amplitude of the input signal S1 is 3 volts, the frequency of the input signal S1 is w, and the input signal S1 has a direct current signal with 1 volts. So the input signal S1 can be formulated as:
S1=1+3 sin (wt)

Because the direct current is a noise signal, the sine wave S1 is input to the first voltage source V1 to filter out the direct current signal. The first voltage source V1 outputs the sine wave S2 to the multiplier 10. The sine wave S2 is:
S2=3 sin (wt)

Then the sine wave S2 is input to two input ends of the multiplier 10 for linear multiplication. Thus, the double frequency signal S3 is produced by the multiplier 10, that is:
S3=3 sin (wt)×3 sin (wt)=−4.5 cos (2 wt)+4.5

Because the signal S3 has another direct current signal, the signal S3 is input to the second voltage source V2 to filter out the direct current signal. Therefore, the double frequency signal S4 output via the output terminal Vout is:
S4=−4.5 cos (2 wt)

From the above mentioned, the signal S4 is a cosine wave and frequency of the signal S4 is twice as frequency of the signal S1 which is input to the frequency double circuit. The frequency double circuit can be applied in doubling frequency of a sine wave, a cosine wave, a triangle wave, a square wave, or other periodic waves.

By means of the same way of the above mentioned, frequency of the signal S4 is capable of multiplying as predetermined times, like 3 times or more, of the frequency of the signal S1 when circuits of and around the multiplier 10 are rearranged.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments.

What is claimed is:

1. A frequency double circuit comprising:
an input terminal for receiving an input signal;
a first voltage source for filtering out a direct current signal of the input signal;
a multiplier comprising two input ends receiving the input signal without the direct current signal for linear multiplication, the multiplier output a double frequency signal;
a second voltage source for filtering out a direct current signal of the double frequency signal from the multiplier; and
an output terminal for output the double frequency signal without the direct current signal from the second voltage source.

2. The frequency double circuit as claimed in claim 1, wherein the input signal is a periodic signal.

3. The frequency double circuit as claimed in claim 1, wherein the first voltage source and the second voltage source are direct current voltage sources.

4. A frequency double circuit for doubling frequency of an input signal, the input signal comprising a periodic signal and a direct current signal, the frequency double circuit comprising:
a first component for filtering out the direct current signal of the input signal;
a multiplier connected to the first component comprising two input ends receiving the periodic signal of the input signal from the first component, the multiplier linear multiplying the periodic signal of the input signal and output a double frequency signal;
a second component for filtering out a direct current signal of the double frequency signal from the multiplier.

5. The frequency double circuit as claimed in claim 4, wherein the first component and the second component are direct current sources.

6. A circuit for multiplying frequency of an input signal, comprising:
a signal input terminal for receiving an input signal comprising at least one periodic signal with a preset frequency;
a signal output terminal electrically connectable with said signal input terminal so as to output signals from said signal input terminal; and
a multiplier electrically connectable between said signal input terminal and said signal output terminal for treating said input signal before said input signal is further transmitted to said signal output terminal, said multiplier capable of multiplying said input signal by itself for a predetermined number of times so as to multiplying said frequency of said at least one periodic signal of said input signal.

7. The circuit as claimed in claim 6, further comprising a voltage source electrically installable between said signal output terminal and said multiplier to compensate for any direct current signal generating in said treated input signal due to multiplying of said multiplier.

8. The circuit as claimed in claim 6, further comprising a voltage source electrically installable between said signal input terminal and said multiplier to compensate for any direct current signal accompanying with said at least one periodic signal in said input signal.
